(19) United States
(12) Patent Application Publication
(10) Pub. No.: US 2002/0033505 A1
(43) Pub. Date: Mar. 21, 2002

(54) Semiconductor integrated circuit device and method of manufacturing the same

(75) Inventors: Hiroshi Kujirai, Kunitachi (JP); Masahiro Moniwa, Sayama (JP)

Correspondence Address: Stanley P. Fisher, Reed Smith Hazel & Thomas LLP, Suite 1400, 3110 Fairview Park Drive, Falls Church, VA, 22042-4503, US

(73) Assignee: Hitachi, Ltd.

(21) Appl. No.: 09/939,748

(22) Filed: Aug. 28, 2001

(30) Foreign Application Priority Data
Sep. 21, 2000 (JP) 2000-286381

(51) Int. Cl. H01L 27/01; H01L 27/12; H01L 31/0392

(52) U.S. Cl. 257/350

(57) ABSTRACT

In order to provide a technique to restrain the punch-through phenomenon of an MISFET constituting a memory cell or the like of a DRAM and to improve the retention time of the memory cell of the DRAM, a threshold value regulating impurity regions SA3 is formed, for example, by implanting BF ions, in a semiconductor substrate under a p-type gate electrode 9p of an information transferring MISFET Qs of the DRAM, and a punch-through preventing region PA is formed to cover end portions of the source and the drain of the information transferring MISFET Qs at a position deeper than the threshold value regulating impurity regions SA3 by implanting an impurity including an atom whose weight is heavier than that of the threshold value regulating impurity atom, for example, In.

### TECHNICAL FIELD OF THE INVENTION

The present invention relates to a semiconductor integrated circuit device and a method of manufacturing the same, and particularly to a semiconductor integrated circuit device having a mixed palletizing type memory in which a DRAM (Dynamic Random Access Memory) or a DRAM memory circuit and a logic circuit are provided in the same semiconductor substrate and a method of manufacturing the same.

### BACKGROUND OF THE INVENTION

A memory cell of the DRAM is comprises one information transferring MISFET and a capacitor connected in series to this MISFET. Although electric charge is stored in the capacitor so that information is stored, since the stored charge is leaked with the lapse of time, periodically reproducing a storage content, so called a refresh operation, is performed. In order to restrain the power consumption of a semiconductor integrated circuit device, it is necessary to lengthen a hold time of stored charge (refresh time). Here, the hold time means the time by which the charge stored in a capacitor connected to a MISFET for selecting a memory cell can be led.

### SUMMARY OF THE INVENTION

However, with the fining down of a memory cell, a phenomenon that a retention time becomes short has been seen. This retention time means a hold time of the worst among, for example, 256 MB.

Examination of this phenomenon by the present inventors resulted in consideration that one of causes of the phenomenon that the retention time becomes short may be the increase in the concentration of impurity in a semiconductor substrate.

That is, with the fining down of an MISFET constituting a memory cell of a DRAM, for example, in an MISFET constituting a memory cell of a DRAM having a gate length of 0.3 μm or less, in order to obtain 1.0 V of threshold voltage, it is necessary to set the impurity concentration of a semiconductor substrate to a high concentration such as at least about 5×10¹⁷ cm⁻³.

When the impurity of a semiconductor substrate is made high concentration, the electric field becomes large in the junction among a source region and drain region (the side connected to a capacitor) of an MISFET constituting a memory cell, and the semiconductor substrate, whereby the junction leak becomes large. As a result, the retention time becomes short.

In order to drive a memory cell of a DRAM while holding down the impurity concentration of a semiconductor substrate, negative word line technique has been proposed. In the negative word line technique, since the gate electrode of the MISFET constituting a memory cell is biased by a negative potential, the threshold voltage can be set low. As a result, the impurity concentration of a semiconductor substrate can be restrained low. For example, there is a description regarding the negative word line technique in IEEE JOURNAL OF SOLID-STATE CIRCUITS, VOL. 30, NO. 11, NOVEMBER 1995, pp. 1183-1188 and the like.

In order to drive a memory cell of a DRAM while holding down the impurity concentration of a semiconductor substrate, the present inventors have considered the negative word line technique described above and have considered making a gate electrode of the MISFET constituting a memory cell P⁺ type.

However, when the impurity concentration of a semiconductor substrate is restrained low through these methods, since the junction leak described above can be reduced, although the retention characteristic can be improved, the punch-through phenomenon is easy to occur, and there is an inconvenience that the leak current increases. That is, when the impurity of a semiconductor substrate is held down, the expanse of the depletion layer extending from the source and the drain becomes large. When this depletion layer is connected, the drain electric field influences even the source to decrease the diffusion potential of the source and the vicinity thereof. As a result, even when a channel is not formed, current comes to flow between the source and the drain (punch-through phenomenon), and the leak current increases.

It is an object of the present invention to provide a technique to restrain the punch-through phenomenon of an MISFET constituting a memory cell and the like of a DRAM.

Another object of the present invention is to provide a technique to improve the retention time of a memory cell of a DRAM.

Still another object of the present invention is to provide a technique to reduce unevenness in characteristics of an MISFET constituting a memory cell of a DRAM.

These and other objects and new features of the present invention will become apparent from the description and the attached drawings of the present disclosure.

The outline of typical inventions among the inventions disclosed in the present application is briefly explained as follows.

A semiconductor integrated circuit device according to the present invention is a semiconductor integrated circuit device having an n-channel type MISFET, and the n-channel type MISFET comprises (a) a source and a drain formed in a semiconductor substrate, (b) a gate electrode formed on the semiconductor substrate between the source and the drain via a gate isolation film and having a p-type impurity, (c) a first impurity region for regulating a threshold value formed in the semiconductor substrate under the gate electrode, and (d) a second impurity region for preventing punch-through formed to cover end portions of the source and the drain at a position deeper than the first impurity region and having an impurity including an atom whose weight is heavier than that of the impurity atom in the first impurity region.

With the means described above, since the second impurity region for preventing punch-through is formed to cover end portions of the source and the drain at a position deeper than the threshold value regulating first impurity region and is formed so as to have an impurity including an atom whose weight is heavier than that of the impurity atom in the first impurity region, even in the case where the gate electrode of the MISFET is made p-type or the gate electrode is biased by a negative potential to be operated as described later on, the punch-through phenomenon of the MISFET can be restrained. The punch-through preventing second impurity region can also include so called a pocket structure.

When the means are applied to a memory cell of a DRAM, while the retention time of the DRAM can be improved, the punch-through phenomenon can be restrained.

The impurity constituting the second impurity region is, for example, In. The impurity constituting the first impurity region is, for example, B or the like. The gate electrode can be made of SiGe.

The n-channel type MISFET can be an information transferring MISFET constituting a DRAM. The gate electrode may not be p-type, and the gate electrode of the transferring MISFET may be biased by a negative potential.

The means can be applied to an information transferring n-channel type MISFET of a semiconductor integrated circuit device having a memory cell comprising of the information transferring n-channel type MISFET and a capacity element formed in a memory cell forming region of a semiconductor substrate and an n-channel type MISFET and a p-channel type MISFET formed in a peripheral circuit forming region.

The means can be applied to the information transferring n-channel type MISFET, and CMIS constituting n-channel type MISFET and p-channel type MISFET can be so called a dual-gate structure.

A method of manufacturing a semiconductor integrated circuit device according to the present invention comprises the steps of forming a first impurity region for regulating a threshold value by implanting an impurity into a semiconductor substrate main surface and forming a second impurity region for preventing punch-through in a region deeper than the first impurity region by implanting an impurity including an atom whose weight is heavier than that of the impurity atom in the first impurity region.

Through such means, the semiconductor integrated circuit device in which the punch-through phenomenon of an MISFET is restrained can be manufactured. Since the punch-through preventing second impurity region is formed employing an atom whose weight is heavier than that of the impurity atom in the threshold value regulating first impurity region, even after going through a heat treatment thereafter, change in the impurity concentration profile in the punch-through preventing second impurity region is small, and the punch-through phenomenon of the MISFET can be effectively restrained. It does not matter which of the threshold value regulating first impurity region forming process and the punch-through preventing second impurity region forming process comes first.

The punch-through preventing second impurity region may be formed by performing so called a pocket ion implantation.

In the case where the means are applied to a semiconductor integrated circuit device having a memory cell comprising an information transferring n-channel type MISFET and a capacity element formed in a memory cell forming region of a semiconductor substrate and CMIS constituting n-channel type MISFET and p-channel type MISFET formed in a peripheral circuit forming region, while the retention time is improved, a semiconductor integrated circuit in which the punch-through phenomenon is restrained can be manufactured.

At this time, an information transferring n-channel type MISFET forming region and a threshold value regulating first impurity region of a CMIS constituting n-channel type MISFET forming region can be formed at the same time.

### BRIEF DESCRIPTION OF THE DRAWINGS

FIG. 1 is an overall top view of a semiconductor chip 1A forming a DRAM of Embodiment 1 of the present invention;

FIG. 2 is an equivalent circuit diagram of the DRAM of Embodiment 1 of the present invention;

FIG. 3 is a main part cross-sectional view of a substrate illustrating a method of manufacturing a semiconductor integrated circuit device according to Embodiment 1 of the present invention;

FIG. 4 is a main part cross-sectional view of the substrate illustrating the method of manufacturing the semiconductor integrated circuit device according to Embodiment 1 of the present invention;

FIG. 5 is a main part cross-sectional view of the substrate illustrating the method of manufacturing the semiconductor integrated circuit device according to Embodiment 1 of the present invention;

FIG. 6 is a main part cross-sectional view of the substrate illustrating the method of manufacturing the semiconductor integrated circuit device according to Embodiment 1 of the present invention;

FIG. 7 is a main part cross-sectional view of the substrate illustrating the method of manufacturing the semiconductor integrated circuit device according to Embodiment 1 of the present invention;

FIG. 8 is a main part cross-sectional view of the substrate illustrating the method of manufacturing the semiconductor integrated circuit device according to Embodiment 1 of the present invention;

FIG. 9 is a main part cross-sectional view of the substrate illustrating the method of manufacturing the semiconductor integrated circuit device according to Embodiment 1 of the present invention;

FIG. 10 is a main part cross-sectional view of the substrate illustrating the method of manufacturing the semiconductor integrated circuit device according to Embodiment 1 of the present invention;

FIG. 11 is a main part cross-sectional view of the substrate illustrating the method of manufacturing the semiconductor integrated circuit device according to Embodiment 1 of the present invention;

FIG. 12 is a main part cross-sectional view of the substrate illustrating the method of manufacturing the semiconductor integrated circuit device according to Embodiment 1 of the present invention;

FIG. 13 is a main part cross-sectional view of the substrate illustrating the method of manufacturing the semiconductor integrated circuit device according to Embodiment 1 of the present invention;

FIG. 14 is a main part cross-sectional view of the substrate illustrating the method of manufacturing the semiconductor integrated circuit device according to Embodiment 1 of the present invention;

FIG. 15 is a main part cross-sectional view of the substrate illustrating the method of manufacturing the semiconductor integrated circuit device according to Embodiment 1 of the present invention;

FIG. 16 is a main part cross-sectional view of the substrate illustrating the method of manufacturing the semiconductor integrated circuit device according to Embodiment 1 of the present invention;

FIG. 17 is a main part cross-sectional view of the substrate illustrating the method of manufacturing the semiconductor integrated circuit device according to Embodiment 1 of the present invention;

FIG. 18 is a main part cross-sectional view of the substrate illustrating the method of manufacturing the semiconductor integrated circuit device according to Embodiment 1 of the present invention;

FIG. 19 is a main part cross-sectional view of the substrate illustrating the method of manufacturing the semiconductor integrated circuit device according to Embodiment 1 of the present invention;

FIG. 20 is a main part cross-sectional view of the substrate illustrating the method of manufacturing the semiconductor integrated circuit device according to Embodiment 1 of the present invention;

FIG. 21 is a main part cross-sectional view of the substrate illustrating the method of manufacturing the semiconductor integrated circuit device according to Embodiment 1 of the present invention;

FIG. 22 is a main part cross-sectional view of the substrate illustrating the method of manufacturing the semiconductor integrated circuit device according to Embodiment 1 of the present invention;

FIG. 23 is a main part cross-sectional view of the substrate illustrating the method of manufacturing the semiconductor integrated circuit device according to Embodiment 1 of the present invention;

FIG. 24 is a main part cross-sectional view of the substrate illustrating the method of manufacturing the semiconductor integrated circuit device according to Embodiment 1 of the present invention;

FIG. 25 is a graph showing one example of concentration profiles of In atoms and B atoms;

FIG. 26 is a main part cross-sectional view of a substrate illustrating a method of manufacturing a semiconductor integrated circuit device according to Embodiment 2 of the present invention;

FIG. 27 is a main part cross-sectional view of the substrate illustrating the method of manufacturing the semiconductor integrated circuit device according to Embodiment 2 of the present invention;

FIG. 28 is a main part cross-sectional view of a substrate illustrating a method of manufacturing a semiconductor integrated circuit device according to Embodiment 3 of the present invention;

FIG. 29 is a main part cross-sectional view of the substrate illustrating the method of manufacturing the semiconductor integrated circuit device according to Embodiment 3 of the present invention; and

FIG. 30 is a main part cross-sectional view of the substrate illustrating the method of manufacturing the semiconductor integrated circuit device according to Embodiment 3 of the present invention.

### DESCRIPTION OF THE PREFERRED EMBODIMENTS

Embodiments of the present invention is explained in detail based upon the drawings below. In all the drawings for explaining the embodiments, like reference numerals are used to indicate functionally similar elements in principle, and the repeating explanation therefor is omitted.

(Embodiment 1)

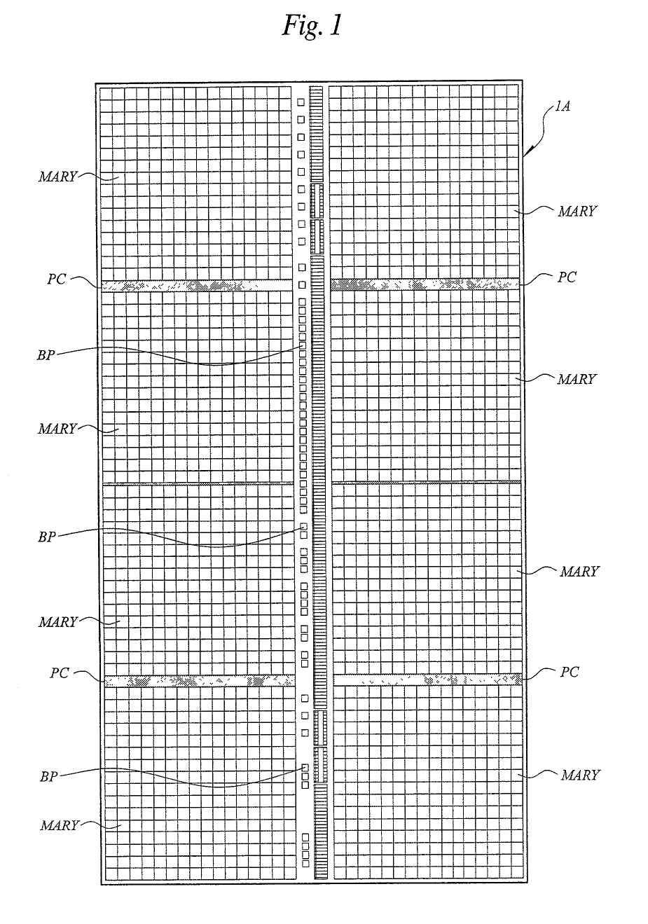

FIG. 1 is an entire top view of a semiconductor chip 1A forming a DRAM of the present embodiment. A DRAM having, for example, 256 Mbits to 1 Gbits of storage capacity, is formed on the main face of the rectangular semiconductor chip 1A. This DRAM has storage sections divided into a plurality of memory arrays (MARY) and peripheral circuit sections (PC) arranged on the periphery thereof. A plurality of bonding pads (BP) connected to wire and the like are arranged on a line in a center part of the semiconductor chip 1A.

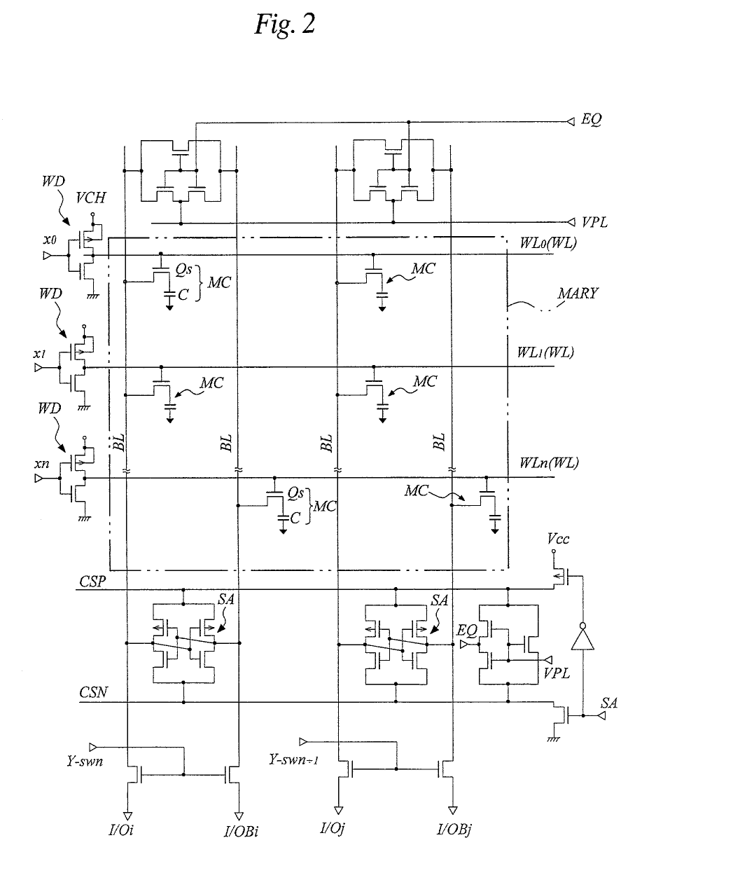

FIG. 2 is an equivalent circuit diagram of the DRAM of the present embodiment. As shown in the diagram, the memory array (MARY) of this DRAM comprises a plurality of word lines WL (WL0, WL1, WLn . . . ) and a plurality of bit lines BL which are arranged in a matrix form, and a plurality of memory cells (MC) arranged at intersection points thereof. One memory cell (MC) storing 1-bit information comprises one information storage capacity element (capacitor) C and one MISFET Qs for selecting one memory cell connected in series to this capacitor. One side of the source and the drain of the information transferring MISFET Qs is electrically connected to the capacitor C, and the other side is electrically connected to the bit line BL. One end of the word line WL is connected to a word driver WD, and one end of the bit line BL is connected to a sense amplifier Sa.

The DRAM of the present embodiment adopts the stacked capacitor structure in which the capacitor C that is the information storage capacity section of a memory cell is arranged over the information transferring MISFET Qs.

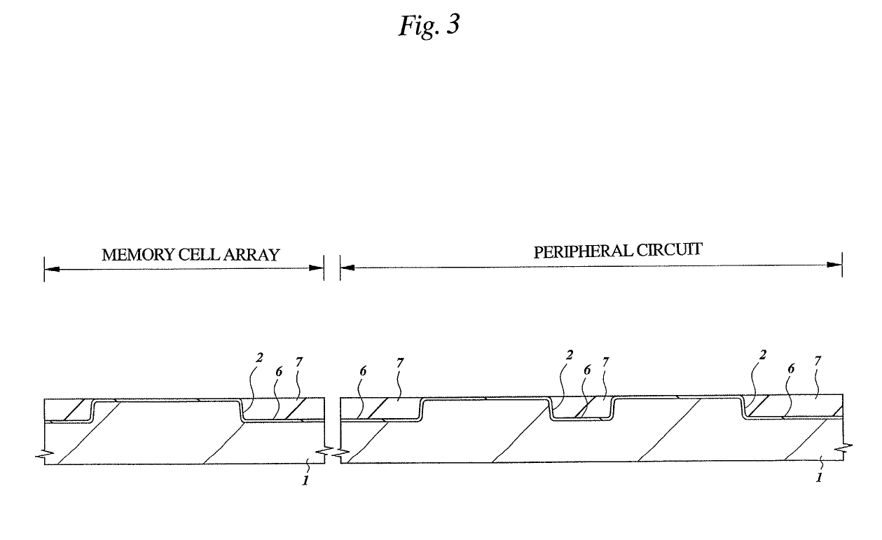

Next, the fabrication method of the DRAM of the present embodiment is explained in the order of processes, employing FIG. 3 to FIG. 24. Left side parts of each drawing showing a section of a substrate illustrate a region (memory cell array) in which memory cells of the DRAM are formed, and right side parts illustrate a peripheral circuit forming region. In the region (memory cell array) in which the memory cells are formed, the memory cells comprising the information transferring n-channel type MISFETs Qs and the capacitors C are formed, and in the peripheral circuit forming region, for example, an n-channel MISFET Qn and a p-channel type MISFET Qp constituting a complementary MISFET are formed.

First, as shown in FIG. 3, for example, an element isolation 2 is formed in a semiconductor substrate 1 made of p-type single crystal silicon having a resistivity of about 1 to 10 Ωcm.

In order to form the element isolation 2, an element isolation region of the substrate 1 is first etched to form grooves having a depth of about 350 nm, and then the substrate 1 is thermally oxidized at about 1100° C. to form a thin silicon oxide film 6 with a film thickness of about 10 nm on the inner walls of the grooves. This silicon oxide film 6 is formed in order to restore the damage due to dry etching occurring on the inner walls of the grooves.

Then, a silicon oxide film 7 is deposited on the substrate 1 including the inner parts of the grooves, and the silicon oxide film 7 over the grooves is chemically and mechanically ground to level the surface thereof to complete the element isolation 2.

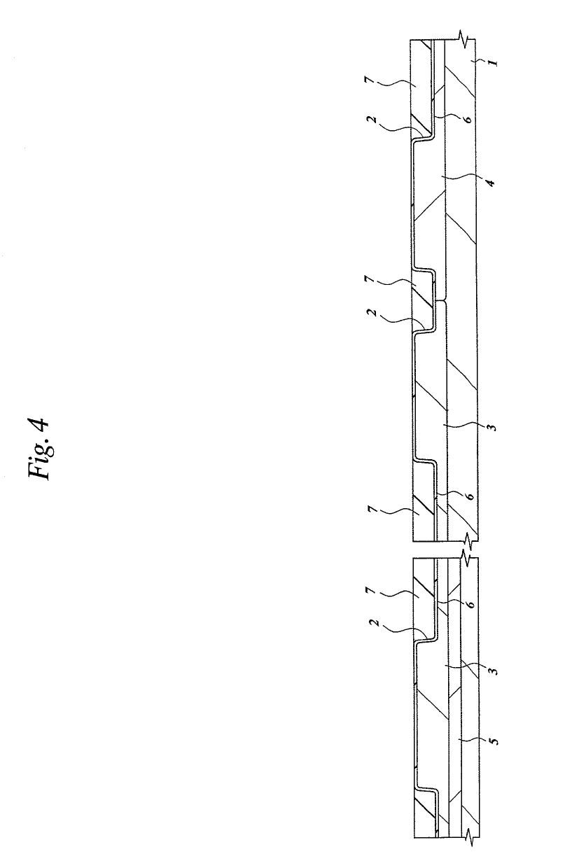

Then, as shown in FIG. 4, after the substrate 1 is implanted with ions of p-type impurity (boron) and n-type impurity (e.g., phosphorus), the impurity is diffused by a heat treatment so that p-type well 3 and n-type well 5 are formed in the memory cell array of the substrate 1, and the p-type well 3 and n-type well 4 are formed in the peripheral circuit region of the substrate 1.

Here, the n-type well 5 of the memory cell array is formed, for example, by injecting about 1×10¹³ cm⁻² P ions with an acceleration energy of 1 MeV. The p-type well 3 of the memory cell array and the p-type well 3 of the peripheral circuit region are formed, for example, by injecting about 1×10¹³ cm⁻²B ions with an acceleration energy of 250 keV, followed by the injection of about 6×10¹² cm⁻² B ions with an acceleration energy of 150 keV, and then by injecting about 5×10¹¹ cm⁻² B ions with an acceleration energy of 40 keV.

The n-type well 4 of the peripheral circuit region is formed, for example, by injecting about 2×10¹³ cm⁻² P ions with an acceleration energy of 500 keV, followed by the injection of about 5×10¹² cm⁻² P ions with an acceleration energy of 250 keV, and then by injecting about 4×10¹² cm⁻² As ions with an acceleration energy of 200 keV.

After the injections of these impurities, a heat treatment is performed at 1000° C. for about 30 minutes. This heat treatment is performed for the activation of impurity ions, restoration for crystal defect which has occurred in the semiconductor substrate 1, or the like.

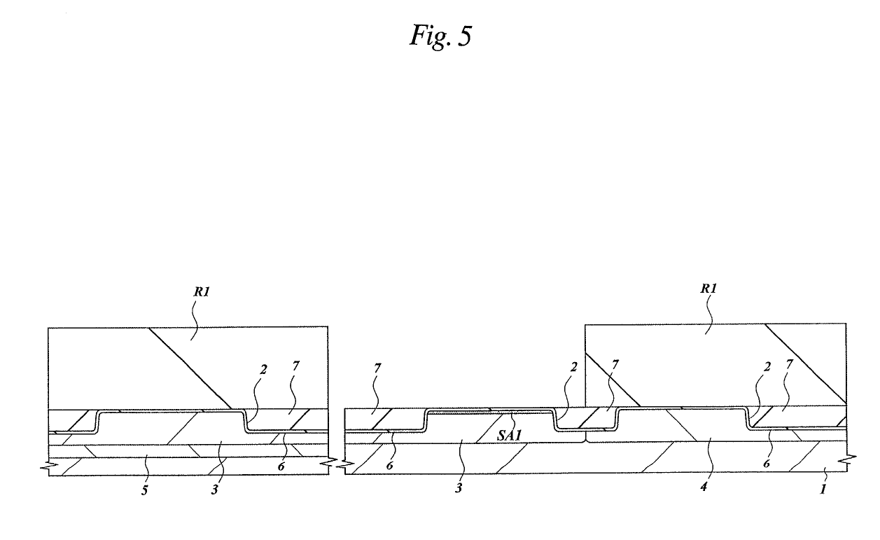

Then, in order to regulate the information transferring n-channel type MISFET Qs and the threshold voltage of the n-channel type MISFET Qn, ions of impurity of the same electric potential type (p-type) as that of the p-type well 3 through which these MISFET are formed are implanted. This ion implantation is explained in detail referring to FIG. 5 to FIG. 8.

As shown in FIG. 5, the area other than the p-type well 3 of the peripheral circuit forming region is covered by a resist film R1, and about 1.4×10¹² cm⁻² BF ions (BF₂⁺) are injected into the main surface of the p-type well 3 of the peripheral circuit forming region with an acceleration energy of 45 keV to form a threshold value regulating impurity region SA1. After that, the resist film R1 is removed.

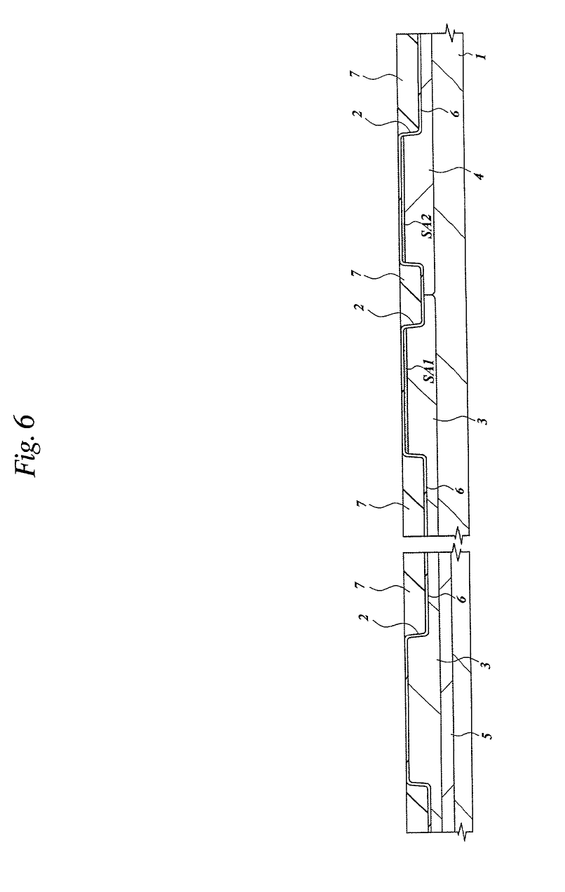

Then, the region other than the n-type well 4 of the peripheral circuit forming region is covered by a resist film R2 (not shown), and about 2×10¹² cm⁻² P ions are injected into the main surface of the n-type well 4 of the peripheral circuit forming region with an acceleration energy of 20 keV to form a threshold value regulating impurity region SA2 (FIG. 6). After that, the resist film R2 is removed. The threshold value regulating impurity region SA2 may be formed after the formation of the above-described p-type well 4.

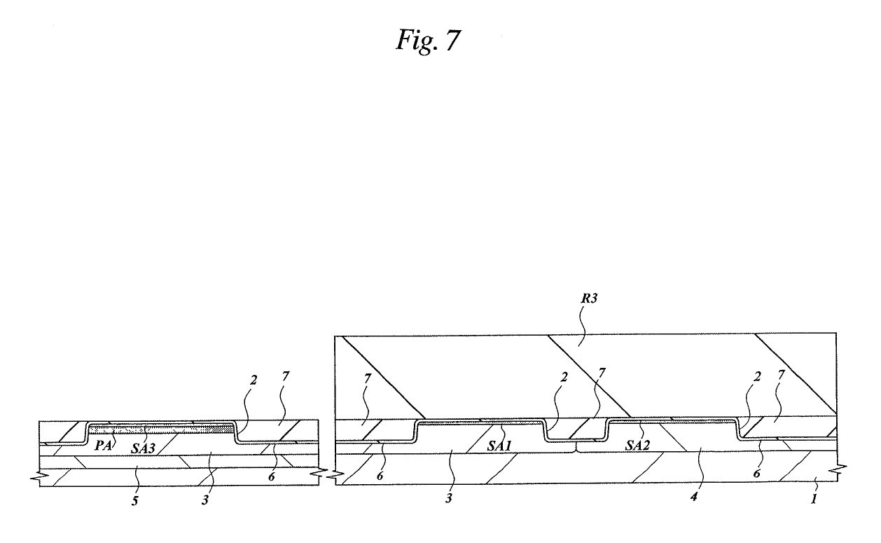

Then, as shown in FIG. 7, the region other than the p-type well 3 of the memory cell array is covered by a resist film R3, and about 0.5 to 5×10¹³ cm⁻² In (indium) ions (In⁺) are injected into the main surface of the p-type well 3 of the peripheral circuit forming region with an acceleration energy of 80 keV, followed by injection of about 1×10¹² cm⁻² BF ions (BF₂⁺) with an acceleration energy of 45 keV to form a threshold value regulating impurity region SA3.

Here, In ions are injected in order to prevent punch-through, the region into which In ions are implanted is called a punch-through prevention region PA. This punch-through is a phenomenon in which current flows between a source and a drain since the depletion layers extending from the source and the drain are connected as described above. Accordingly, the punch-through prevention region PA is LDD type source and drain regions (n⁻ type semiconductor region 11) extending under the gate electrode (channel region), and it is effective to form the region PA so as to cover an end part existing under the gate electrode.

In FIG. 7, the punch-through prevention region PA is formed so as to extend to a position deeper than the source and drain regions (n⁺ type semiconductor region 17) described later on. However, the depth of the punch-through prevention region PA may be deeper than the n⁻ type semiconductor region 11 and shallower than the n⁺ type semiconductor region 17. The punch-through can be prevented even when the depth is shallower than the n⁻ type semiconductor region 11. After that, the resist film R3 is removed.

A resist film may be formed above the n-type well 4, and In ions and BF ions may be injected into the p-type well 3 of the peripheral circuit forming region and the p-type well 3 of the peripheral circuit forming region of the memory cell array to form the threshold value regulating impurity regions SA1, SA3 and the punch-through prevention region PA. In this case, although the punch-through prevention region is formed even in the p-type well 3 of the peripheral circuit forming region, since the concentration of In ions is low, the influence exerted upon the n-channel type MISFET formed on the p-type well 3 of the peripheral circuit forming region is small.

The punch-through prevention region PA3 may be formed after the threshold value regulating impurity regions SA3 (SA1) is formed. The threshold value regulating impurity region SA3 may be formed by injection of B ions. The threshold value regulating impurity region SA3 may be formed by injection of In ions.

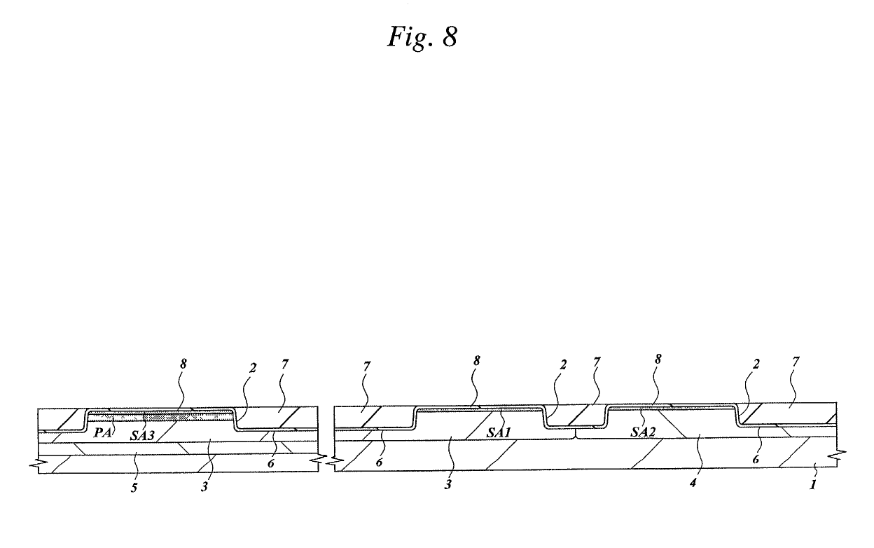

Then, as shown in FIG. 8, after the surface of the substrate 1 (the p-type well 3 and the n-type well 4) is wetly cleaned employing cleaning fluid of a hydrofluoric acid, a clean gate oxide film 8 having a thickness of about 6 nm is formed on each surface of the p-type well 3 and the n-type well 4 by thermal oxidation of about 800° C. This gate oxide film 8 may comprise a silicon oxynitride film containing silicon nitride in a part thereof.

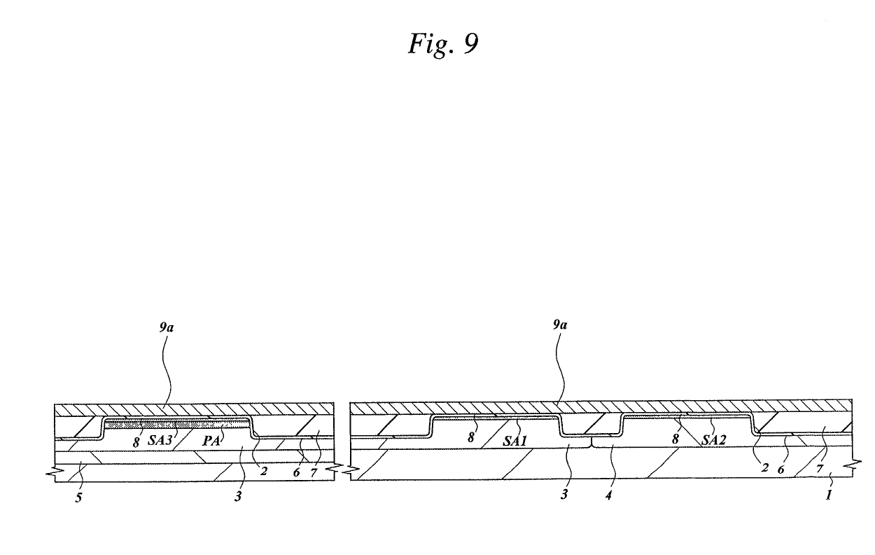

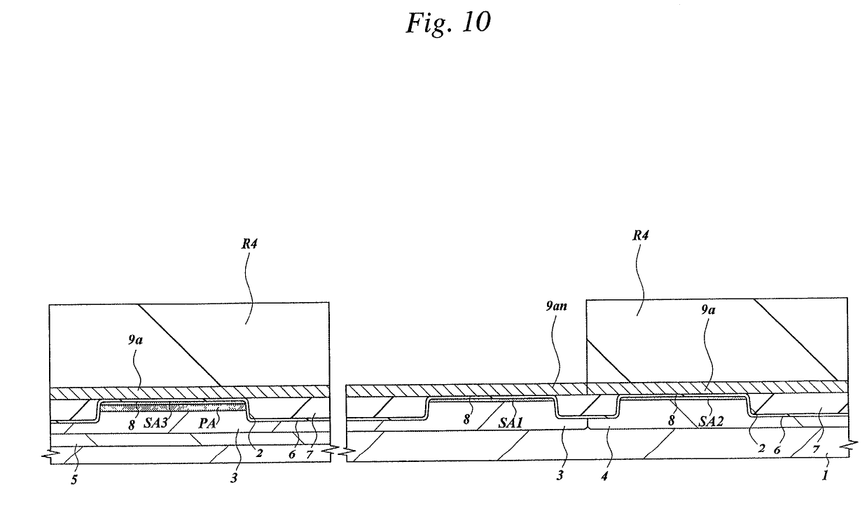

Then, as shown in FIG. 9, a low resistance polycrystal silicon film 9a having a thickness of about 100 nm is deposited over the gate oxide film 8 by a CVD method. After that, as shown in FIG. 10, the region other than the p-type well 3 of the peripheral circuit forming region is covered by a resist film R4, and about 2×10¹⁵ cm⁻² P ions are injected into the low resistance polycrystal silicon film 9a on the p-type well 3 of the peripheral circuit forming region with an acceleration energy of 10 keV to make an n-type 9an of the low resistance polycrystal silicon film 9a.

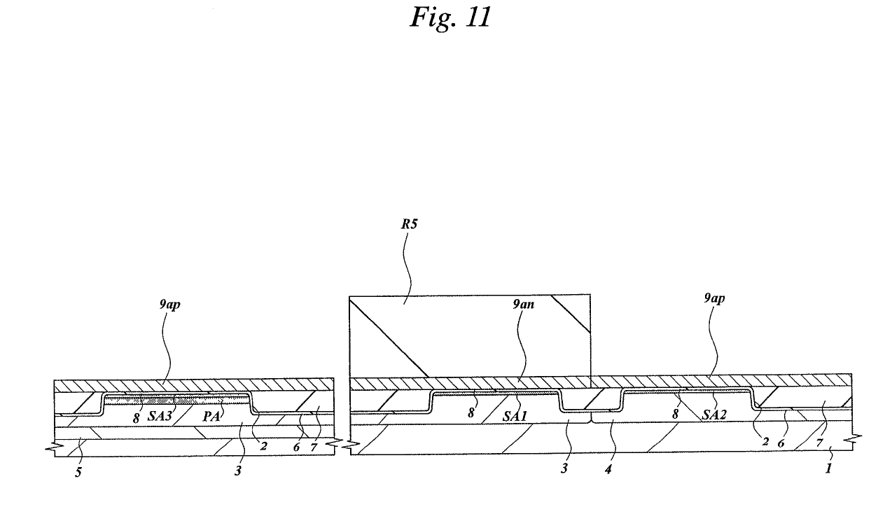

Then, the resist film R4 is removed, a resist film R5 is formed above the p-type well 3 of the peripheral circuit forming region, and about 2×10¹⁵ cm⁻² B ions are injected into the low resistance polycrystal silicon film 9a above the p-type well 3 of the memory cell array and the n-type well 4 of the peripheral circuit forming region with an acceleration energy of 3 keV to make a p-type 9ap of the low resistance polycrystal silicon film 9a as shown in FIG. 11. After that, the resist film R5 is removed.

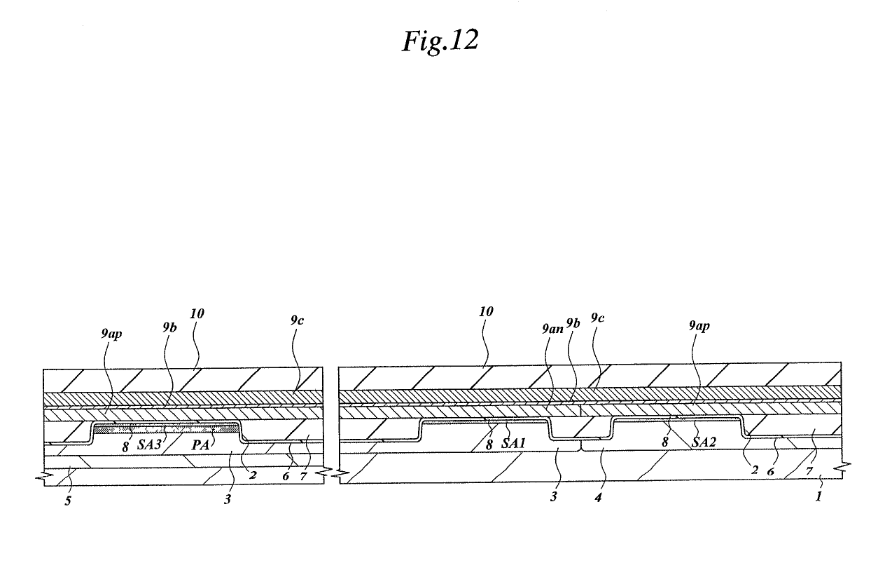

Then, as shown in FIG. 12, a WN film 9b having a thickness of about 5 nm and a W film 9c having a thickness of about 80 nm are deposited over the low resistance polycrystal silicon films 9an, 9ap by a sputtering method, and further a silicon nitride film 10 having a thickness of about 220 nm is deposited over them by a CVD method.

Then, a heat treatment is performed in an inert gas atmosphere such as nitrogen at about 800° C. for the purpose of stress relaxation of the W film 9c and densifying the WN film 9b.

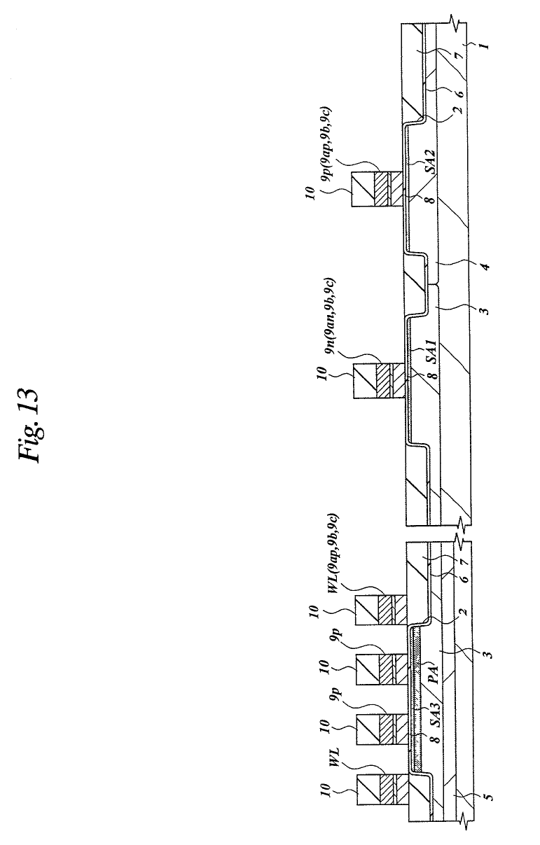

Thereafter, dry etching is performed for the silicon nitride film 10, the W film 9c, the WN film 9b, and the polycrystal silicon film 9a while using a resist film (not shown) as a mask to form n-type or p-type gate electrodes 9n, 9p (FIG. 13). That is, the p-type gate electrode 9p is formed above the p-type well 3 of the memory cell array and above the n-type well 4 of the peripheral circuit region. The n-type gate electrode 9n is formed above the p-type well 3 of the peripheral circuit region. This n-type gate electrode 9n comprises the n-type polycrystal silicon film 9an, the WN film 9b, and the W film 9c, and the p-type gate electrode 9p comprises the p-type polycrystal silicon film 9ap, the WN film 9b, and the W film 9c. A cap insulating film comprising the silicon nitride film 10 is formed on these gate electrodes 9n, 9p. The gate electrode 9p formed in the memory cell array functions as a word line WL.

Then, a thin oxide film (not shown) having a thickness of about 4 nm is formed on the side walls of the polycrystal silicon films 9an, 9ap by wet hydrogen oxidation. By this wet hydrogen oxidation, only silicon (the polycrystal silicon 9an, 9ap, the silicon substrate) can be selectively oxidized without oxidizing the W film 9c.

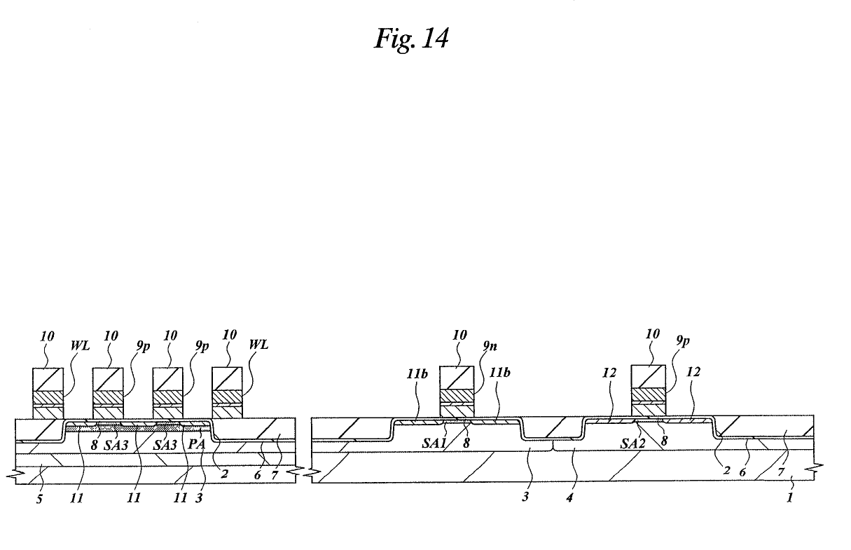

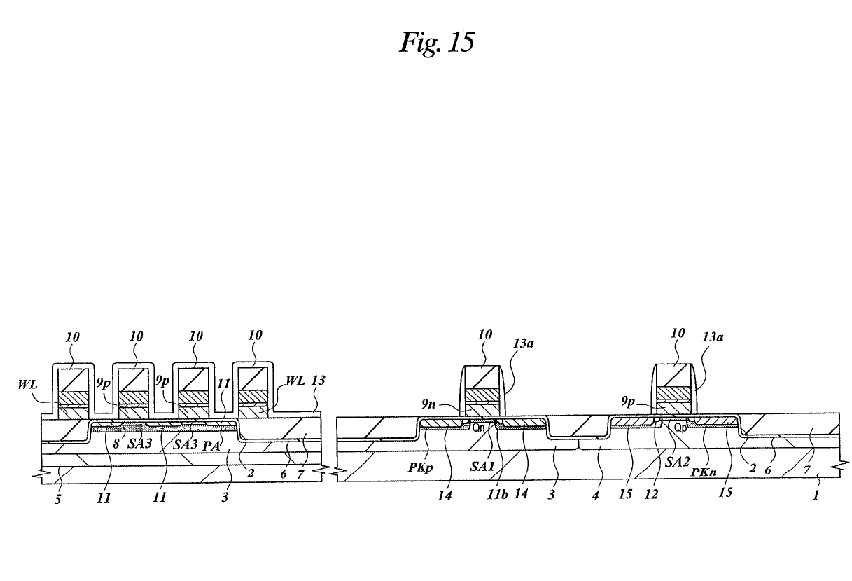

Then, as shown in FIG. 14, about 2.0×10¹³ cm⁻² P ions are implanted into both sides of the gate electrode 9p above the p-type well 3 of the memory cell array at 10 keV to form the n⁻ type semiconductor region 11. Thereafter, by implanting about 2.0×10¹³ cm⁻² P ions at 10 keV and about 7.0×10¹³ cm⁻² As ions at 20 kev into both sides of the gate electrode 9n above the p-type well 3 of the peripheral circuit forming region, an n type semiconductor region 11b is formed. Prior to the formation of this n⁻ type semiconductor region 11b, about 4.0×10¹³ cm⁻² B ions may be implanted at 25 keV to form a pocket ion region PKp covering the n⁻ type semiconductor region 11b (FIG. 15).

About 1.0×10¹⁴ cm⁻² BF ions are then injected into both sides of the gate electrode 9p above the n-type well 4 of the peripheral circuit forming region at 10 keV by ion implantation to form a p⁻ type semiconductor region 12. Prior to the formation of this p⁻ type semiconductor region 12, about 2.0×10¹³ cm⁻² P ions may be implanted at 10 keV, followed by ion implantation of about 6.0×10¹³ cm⁻² P ions at 60 keV by diagonal ion implantation to form a pocket ion region PKn covering the p⁻ type semiconductor region 12 (FIG. 15).

These pocket ion regions PKp, PKn are formed so as to restrain the expanse of the depletion layer from the source and the drain and to reduce the leak current due to the punch-through phenomenon.

Then, as shown in FIG. 15, after a silicon nitride film 13 with a thickness of about 50 nm is deposited above the substrate 1 by a CVD method, a side wall spacer 13a is formed on the side walls of the gate electrodes 9n, 9p of the peripheral circuit region, by covering the upper part of the substrate 1 of the memory cell array by a photoresist film (not shown) and anisotropically etching the silicon nitride film 13 of the peripheral circuit region.

About 3.0×10¹⁵ cm⁻² As ions are then injected into both sides of the gate electrode 9n above the p-type well 3 of the peripheral circuit forming region at 80 keV to form an n⁺ type semiconductor region 14. Thereafter, about 5.0×10¹⁵ cm⁻² BF ions are injected into both sides of the gate electrode 9p above the n-type well 4 of the peripheral circuit forming region at 30 keV to form a P⁺ type semiconductor region 15 (source, drain). Through the processes so far, formed are an n-channel type MISFET Qn and a p-channel type MISFET Qp provided with LDD (Lightly Doped Drain) structure source and drain (n⁻ type semiconductor region 11b, n⁺ type semiconductor region 14, p⁻ type semiconductor region 12, and P⁺ type semiconductor region 15).

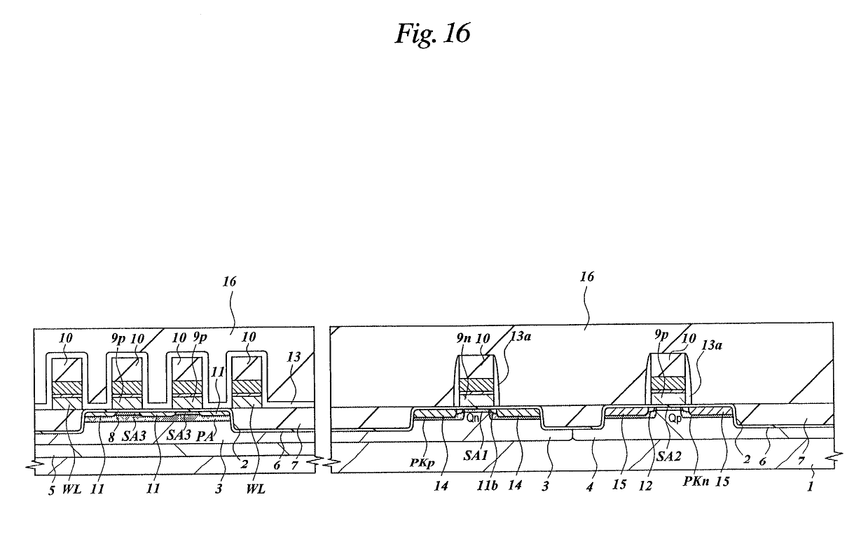

As shown in FIG. 16, a silicon oxide film 16 is then formed over the gate electrodes 9n, 9p.

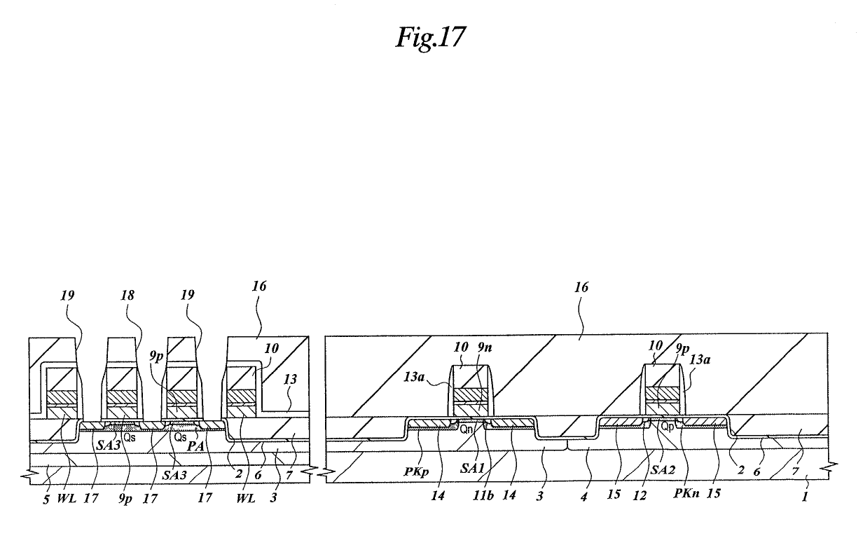

Thereafter, dry etching is performed for the silicon oxide film 16 above the n⁻ type semiconductor region 11 of the memory cell array, using a photoresist mask film (not shown) as a mask to expose the surface of the silicon nitride film 13 as shown in FIG. 17. Then, the exposed silicon nitride film 13 is dryly etched to form contact holes 18, 19 on the n⁻ type semiconductor region 11.

This etching for the silicon oxide film 16 is performed under a condition that the etching speed of the silicon oxide becomes larger compared with that of the silicon nitride so that the silicon nitride film 13 is not removed completely. The etching of the silicon nitride film 13 is performed under a condition that the etching speed of the silicon nitride becomes larger compared with those of silicon (substrate) and the silicon oxide so that the substrate 1 and the silicon oxide film 7 are not removed deeply. Further, the etching of the silicon nitride film 13 is performed under a condition that the silicon nitride film 13 anisotropically etched so as to leave the silicon nitride film 13 on the side walls of the gate electrode 9 (word line WL). Thus, the contact holes 18, 19 having fine diameters are formed with respect to the gate electrode 9 (word line WL) by a self-alignment.

Then, about 1.0×10¹³ cm⁻² As ions are injected into the p-type well 3 (n⁻ type semiconductor region 11) of the memory cell array through the contact holes 18, 19 at 20 keV to form the n⁺ type semiconductor region 17 as shown in FIG. 17. Through the processes so far, formed is an information transferring MISFET Qs made of the n-channel type in the memory cell array.

Thus, by making the n-type of the gate electrode 9n of the n-channel type MISFET Qn in the peripheral circuit forming region and the p-type of the gate electrode 9p of the p-channel type MISFET Qp (so called a dual-gate structure), a channel is formed on the surface of the substrate, and the subthreshold characteristic and the short channel effect are improved.

The information transferring MISFET Qs of the memory cell array is an n-channel type MISFET, and since the gate electrode 9p of this MISFET Qs is made the p-type, a threshold value Vt of the information transferring MISFET Qs can be made high. This is because the work function of the p-type polycrystal silicon is about 5.15 V and is, for example, about 1 V larger than that of the polycrystal silicon (4.15 V). Accordingly, in the case where the gate electrode of the information transferring MISFET Qs is made the p-type, the threshold value thereof can be made about 1 V higher, compared with that of the case where the gate electrode is made the n-type. Here, the concentration of the substrate is supposed to be the same.

As a result, the substrate concentration (threshold value regulating impurity region SA3) corresponding to the increase in the threshold value can be reduced, and the junction leak of the n⁺ type semiconductor region 17 connected to a capacitor C described later on can be reduced. Thus, the retention characteristic of the memory cell array can be improved.

Even when the substrate concentration is reduced, since the punch-through prevention region PA is formed, the expanse of the depletion layer from the source and the drain can be restrained, and the increase of the leak current due to the punch-through phenomenon can be prevented.

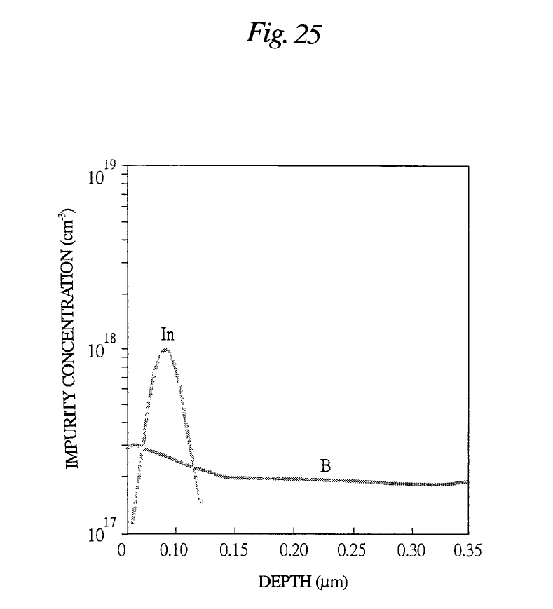

Since the punch-through prevention region PA is formed by injecting In atoms, and since the mass of an In atom is larger than that of a B atom and the diffusion coefficient of In atom is smaller than that of B atom, In atoms can be made exist in a desired region at a sharp concentration profile, thereby not bringing about the increase in the substrate concentration (the threshold value regulating impurity region SA3). FIG. 25 is an example of the concentration profile of In atoms and B atoms. The axis of ordinate represents the concentration of impurity (cm⁻³), and the axis of abscissa represents the depth from the substrate surface (μm). Here, B atoms constituting the threshold value regulating impurity exist at a position of about 0.02 μm of depth from the substrate surface. Although the activation rate of In is low, even considering this activation rate, the peak concentration thereof is 5×10¹⁷ cm⁻³ and is larger compared with B atom concentration. In this case, the depth of the n⁺ type semiconductor region 17 is about 0.15 μm. Thus, In atoms can be made exist at a sharp concentration profile, and the increase in the leak current due to the punch-through phenomenon can be prevented.

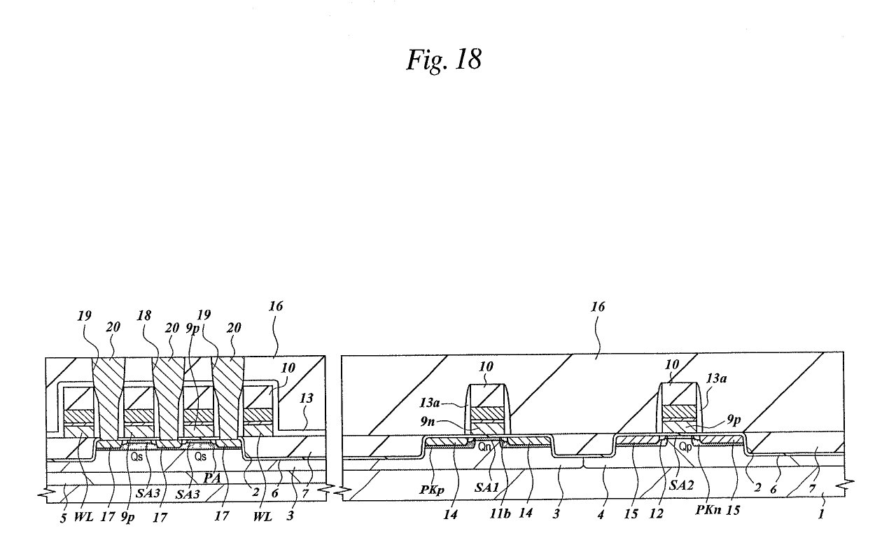

Then, plugs 20 are formed inside the contact holes 18, 19, and through these plugs, the capacitor C and the bit line BL connected to the n⁺ type semiconductor region 17 are formed. In the peripheral circuit forming region, wire connected to the n⁺ type semiconductor region 14 or the P⁺ type semiconductor region 15 of the n-channel type MISFET Qn or the p-channel type MISFET Qp via the plug is formed. One example of the capacitor C, bit line BL, plugs, and forming processes of the wire is explained below referring to FIG. 18 to FIG. 24.

As shown in FIG. 18, the plugs 20 are formed inside the contact holes 18, 19. In order to form these plugs 20, first, the inside of the contact holes 18, 19 is wetly cleaned using cleaning fluid containing hydrofluoric acid, and then a low resistance polycrystal silicon film obtained by doping the n-type impurity such as phosphorus (P) into the upper part of the SOG film 16 including the inside of the contact holes 18, 19 is deposited by a CVD method, followed by etching back (or grinding by a CMP method) of this polycrystal silicon film to leave it only inside the contact holes 18, 19.

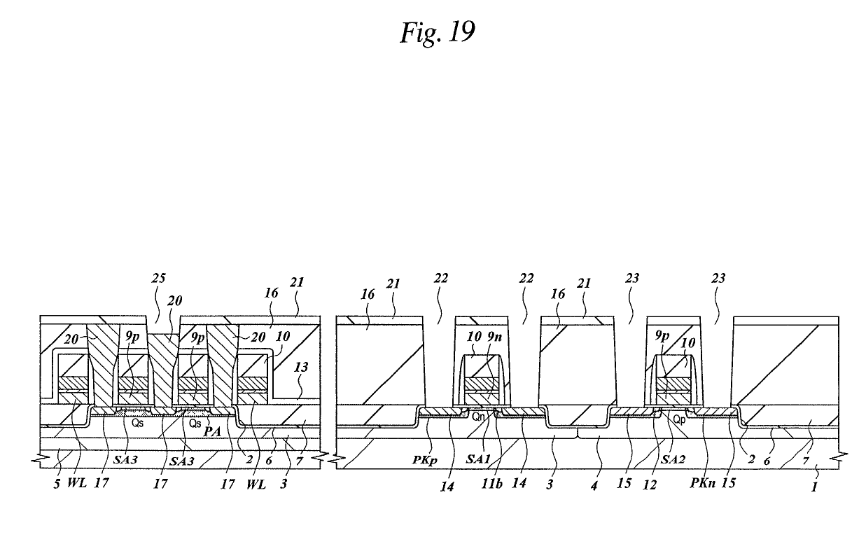

Then, as shown in FIG. 19, after a silicon oxide film 21 with a thickness of about 20 nm is deposited over the SOG film 16 by a CVD method, the silicon oxide film 21 of the peripheral circuit region and the SOG film 16 of the lower layer thereof are dryly etched employing a photoresist film (not shown) as a mask to form a contact hole 22 on the n⁺ type semiconductor region 14 of the n-channel type MISFET Qn and to form a contact hole 23 on the P⁺ type semiconductor region 15 of the p-channel type MISFET Qp. At the same time, a through hole 25 is formed on the contact hole 18 of the memory cell array.

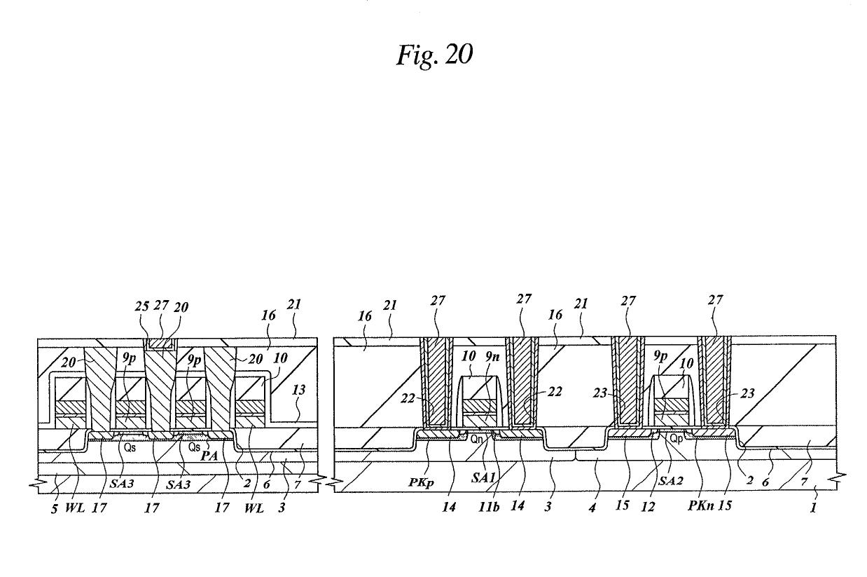

Then, as shown in FIG. 20, after silicide film (not shown) is formed on each of the surface of the n⁺ type semiconductor region 14 of the n-channel type MISFET Qn, the surface of the P⁺ type semiconductor region 15 of the p-channel type MISFET Qp, and the surface of the plug 20 of the inside of the contact hole 18, a plug 27 is formed inside the contact holes 22, 23, 24 and inside the through hole 25.

The silicide film is formed by depositing Ti film with a thickness of about 30 nm and TiN film with a thickness of about 20 nm, for example, on the silicon oxide film 21 including the inside of the contact holes 22, 23, 24 and the inside of the through hole 25 by a sputtering method, followed by a heat treatment of about 650° C. for the substrate 1. The plug 27 is formed by depositing TiN film with a thickness of about 50 nm and W film with a thickness of about 300 nm, for example, on the TiN film 21 including the inside of the contact holes 22, 23, 24 and the inside of the through hole 25 by a CVD method, followed by grinding of W film, TiN film, and Ti film on the silicon oxide film 21 by a CMP method so as to leave these films only inside the contact holes 22, 23, 24 and inside the through hole 25. Since the contact resistance between the source and drain (the n⁺ type semiconductor region 14, the P⁺ type semiconductor region 15) and the plug 27 can be reduced by forming the suicide film, the operating speed of the MISFET (the n-channel type MISFET Qn, the p-channel type MISFET Qp) constituting the peripheral circuit is improved.

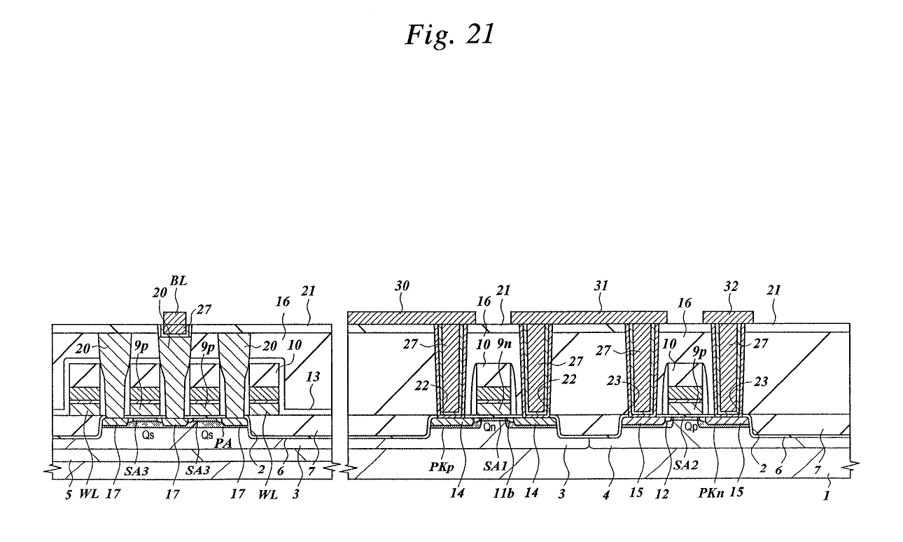

Then, as shown in FIG. 21, the bit line BL is formed on the silicon oxide film 21 of the memory cell array, and first layers of wirings 30 to 33 are formed over the silicon oxide film 21 of the peripheral circuit region. The bit line BL and the first layers of wirings 30 to 33 are formed by depositing W film with a thickness of about 100 nm, for example, on the silicon oxide film 21 by a sputtering method, followed by dry etching of W film, using a photoresist film as a mask.

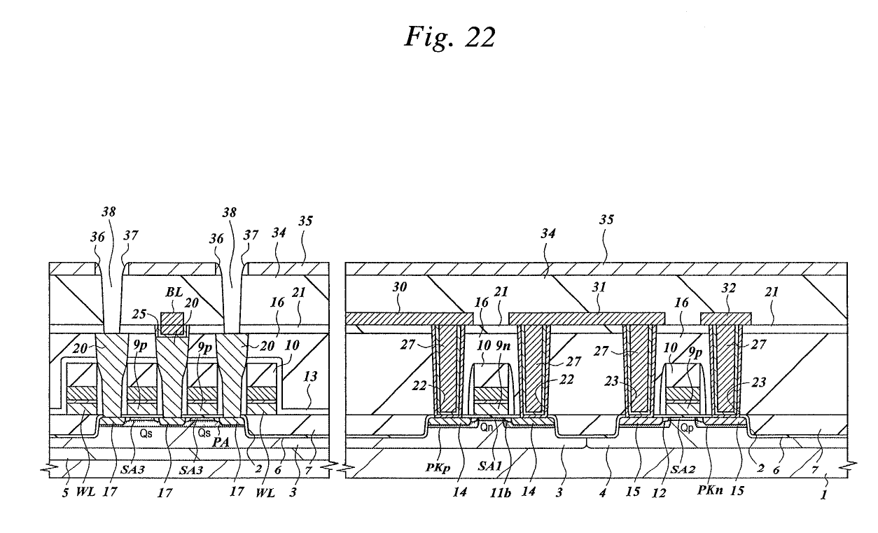

As shown in FIG. 22, an SOG film 34 with a thickness of about 300 nm is then formed over the bit line BL and the first layers of wirings 30 to 33. This SOG film 34 is formed by a method similar to that for the SOG film 16.

Then, after a polycrystal silicon film 35 with a thickness of about 200 nm is deposited over the SOG film 34 by a CVD method, the polycrystal silicon film 35 of the memory cell array is dryly etched, using a photoresist film as a mask, to form a groove 36 in the polycrystal silicon film 35 above the contact hole 19.

After a side wall spacer 37 is formed on the side wall of the groove 36, the SOG film 34 and the silicon oxide film 21 of the lower layer thereof are dryly etched, employing the side wall spacer 37 and the polycrystal silicon film 35 as a mask to form a through hole 38 above the contact hole 19. The side wall spacer 37 of the side wall of the groove 36 is formed by depositing a polycrystal silicon film on the polycrystal silicon film 35 including the inside of the groove 36 by a CVD method, followed by anisotropic etching of that polycrystal silicon film to leave it in the side walls of the groove 36. Thus, even when the memory cell size is reduced, since a matching margin between the bit line BL and the through hole 38 is ensured, a short circuit between a plug 39 embedded in the through hole 38 at the next process and the bit line BL can be prevented.

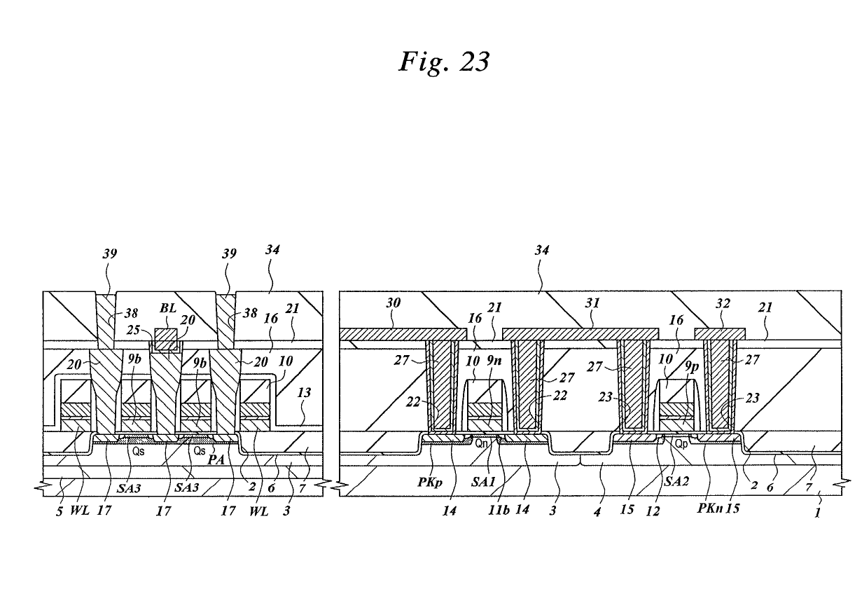

Then, after the polycrystal silicon film 35 and the side wall spacer 37 are removed by dry etching, the plug 39 is formed inside the through hole 38 as shown in FIG. 23. The plug 39 is formed by depositing by a CVD method a low resistance polycrystal silicon film obtained by doping an n-type impurity (phosphorus) into the upper part of the SOG film 34 including the inside of the through hole 38 and then by etch back of that polycrystal silicon film to leave it only inside the through hole 38.

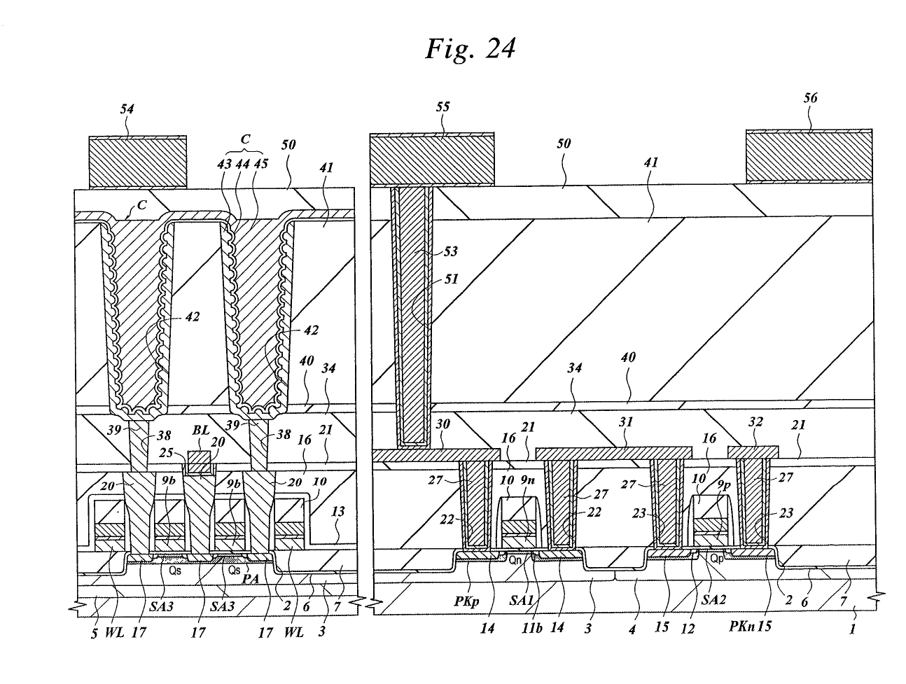

Thereafter, as shown in FIG. 24, a silicon nitride film 40 with a thickness of about 100 nm is deposited over the SOG film 34 by a CVD method, and after a silicon oxide film 41 is deposited over the silicon nitride film 40 by a CVD method, the silicon oxide film 41 of the memory cell array is dryly etched employing a photoresist film (not shown) as a mask, and then the silicon nitride film 40 that is a lower layer of that silicon oxide film 41 is dryly etched to form a groove 42 above the through hole 38.

Then, after an amorphous silicon film 43a with a thickness of about 50 nm into which an n-type impurity (phosphorus) is doped is deposited over the silicon oxide film 41 including the inside of the groove 42 by a CVD method, the amorphous silicon film 43a over the silicon oxide film 41 is eliminated by etch back to leave the amorphous silicon film 43a along the inside wall of the groove 42.

After the surface of the amorphous silicon film 43a left inside the groove 42 is wetly cleaned by cleaning fluid of a hydrofluoric acid, monosilane (SiH₄) is supplied to the surface of the amorphous silicon film 43a in a reduced pressure atmosphere, and then a heat treatment is performed for the substrate 1 to polycrystallize the amorphous silicon film 43a and to make silicon grains grow on the surface thereof. Thus, a polycrystal silicon film 43 whose surface is roughened is formed along the inner wall of the groove 42. This polycrystal silicon film 43 is employed as a lower electrode of the capacitor.

Then, after a tantalum oxide (Ta₂O₅) film 44 with a thickness of about 15 nm is deposited over the silicon oxide 41 including the inside of the groove 42 by a CVD method, a heat treatment is performed in an oxygen atmosphere at about 800° C. for 3 minutes to crystallize the tantalum oxide film 44 and to supply oxygen to the film to restore defect. This tantalum oxide film 44 is employed as a capacity isolation film of the capacitor.

Thereafter, a TiN film 45 with a thickness of about 150 nm is deposited on the tantalum oxide film 44 including the inside of the groove 42, employing a CVD method and a sputtering method, and then the TiN film 45 and the tantalum oxide film 44 are dryly etched employing a photoresist film (not shown) as a mask to form the capacitor C comprising an upper electrode made of the TiN film 45, the capacity isolation film made of the tantalum oxide film 44, and a lower electrode made of the polycrystal silicon film 43. With the processes so far, a memory cell of a DRAM comprising a memory cell selecting MISFET Qs and a capacitor C connected thereto in series is completed.

A silicon oxide film 50 with a thickness of 100 nm is deposited above the capacitor C by a CVD method. The silicon oxide films 50, 41, the silicon nitride film 40, and the SOG film 34 on the first layer wirings 30, 33 of the peripheral circuit region, employing a photoresist film (not shown) as a mask are dryly etched to form a through hole 51 and then to form a plug 53 inside the through hole 51.

Then, second layers of wirings 54 to 56 are formed on the silicon oxide film 50. Third layers of wirings are formed on the second layers of wirings 54 to 56 via the SOG film, and passivation film comprising the silicon oxide film and the silicon nitride film is deposited on the third layers wirings 62, 63, whose drawing is omitted. Through the processes described above, the DRAM of the present embodiment is roughly completed.

(Embodiment 2)

Although the gate electrodes 9n, 9p are formed after the punch-through prevention region is formed in Embodiment 1, in the present embodiment, the pocket ion region to prevent the punch-through is formed employing In ions after the gate electrodes 9n, 9p are formed.

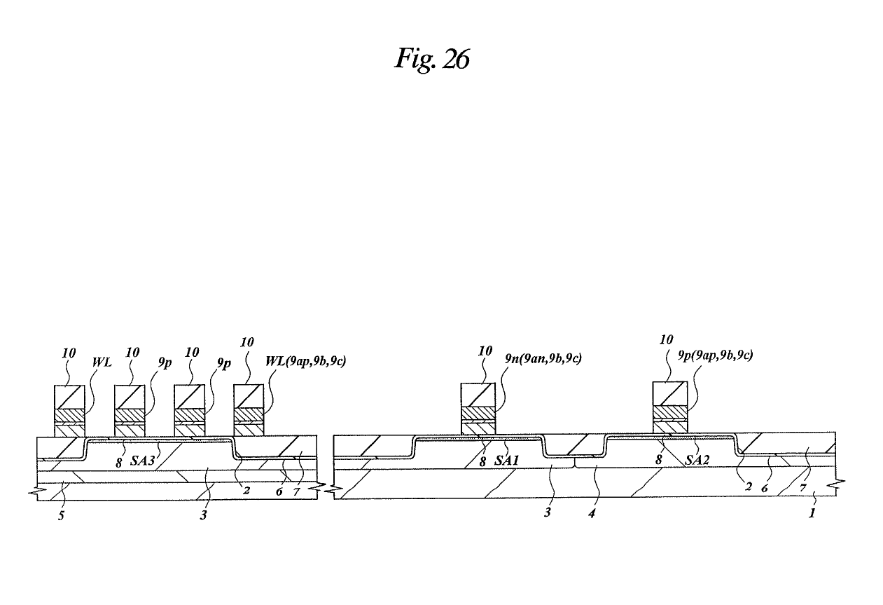

Similarly to Embodiment 1, first n-type and p-type gate electrodes 9n, 9p are formed (FIG. 13). However, the injection of In ions (the formation of the punch-through prevention region PA) is not performed, and only a threshold value regulating regions is formed in the p-type well 3 of the memory cell array as shown in FIG. 26.

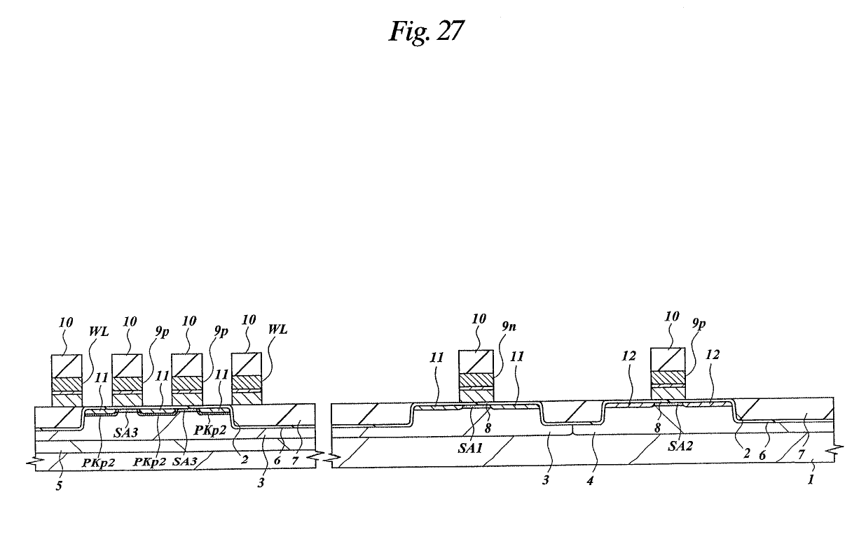

A thin oxide film (not shown) with a film thickness of about 4 nm is then formed on the side walls of the polycrystal silicon film 9an, 9ap by wet hydrogen oxidation. As shown in FIG. 27, In ions are injected into both sides of the gate electrode 9p above the p-type well 3 of the memory cell array by diagonal ion implantation to form a p⁻ type semiconductor region PKp2. Then, about 2.0×10¹³ cm⁻² P ions are injected into both sides of the gate electrode 9p above the p-type well 3 of the memory cell array at 10 keV to form the n⁻ type semiconductor region 11.

Thereafter, the n⁻ type semiconductor region 11b is formed similarly to the case of Embodiment 1. Or the pocket ion region PKp covering the n⁻ type semiconductor region 11b may be formed. Then, the p⁻ type semiconductor region 12 is formed. Or the pocket ion region PKn covering the p⁻ type semiconductor region 12 may be formed.

Since the following processes are similar to those of the case of Embodiment 1 explained referring to the drawings after FIG. 15, the explanation thereof is omitted.

Thus, in the present embodiment, since In ions are injected by diagonal ion implantation to form the p⁻ type semiconductor region PKp2, the expanse of the depletion layer from the source and the drain can be restrained, and the leak current due to the punch-through phenomenon can be reduced. Since the mass of an In atom is larger than that of a B atom and the diffusion coefficient of In atom is smaller than that of B atom, In atoms can be made exist in a desired region at a sharp concentration profile, thereby not bringing about an increase in the substrate concentration (the threshold value regulating impurity region SA3).

Further, since the gate electrode 9p of the MISFET Qs is made the p-type similarly to the case of Embodiment 1, the threshold value Vt of the information transferring MISFET Qs can be made high. As a result, the junction leak of the n⁺ type semiconductor region 17 can be reduced, and the retention characteristic of the memory cell can be improved.

As described above, in order to prevent the punch-through, it is effective to form the pocket ion region PKp2 so as to cover an end part that is the LDD type source and drain regions (n⁻ type semiconductor region 11) extending under the gate electrode (channel region) and exists under the gate electrode. For that purpose, although it is necessary to minimize the angle of the diagonal ion implantation with respect to the semiconductor substrate surface, with the fineness progression of a memory cell array, when the pitch of a gate electrode is small, a limitation in the injection angle of ions occurs. That is, ions cannot be injected since being shielded by the gate electrode. Accordingly, depending upon the pitch of a gate electrode, Embodiment 1 is more effective.

(Embodiment 3)

Although the gate electrodes 9n, 9p are formed by injecting P ions or B ions into the polycrystal silicon film 9a in Embodiment 1, in the present embodiment, an SiGe film 209a is employed.

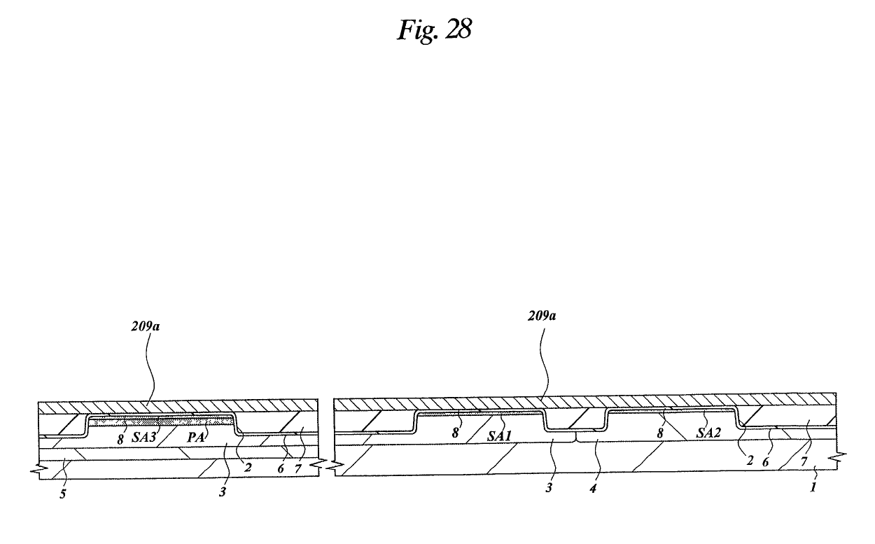

First, the semiconductor substrate 1 shown in FIG. 8 is prepared, and the SiGe film 209a with a thickness of about 100 nm is deposited by a CVD method (FIG. 28). At this time the SiGe film 209a is deposited by a CVD method in which silane (SiH₄), germane (GeH₄), and diborane (B₂H₆) are employed as source gas. In this case, the conductive type of the SiGe film 209a is p-type. This is because the work function of the gate electrode is made in the approximately middle of the n-type polycrystal silicon and the p-type polycrystal silicon as described later on. The semiconductor substrate shown in FIG. 8 is formed through processes similar to those of the case of Embodiment 1.

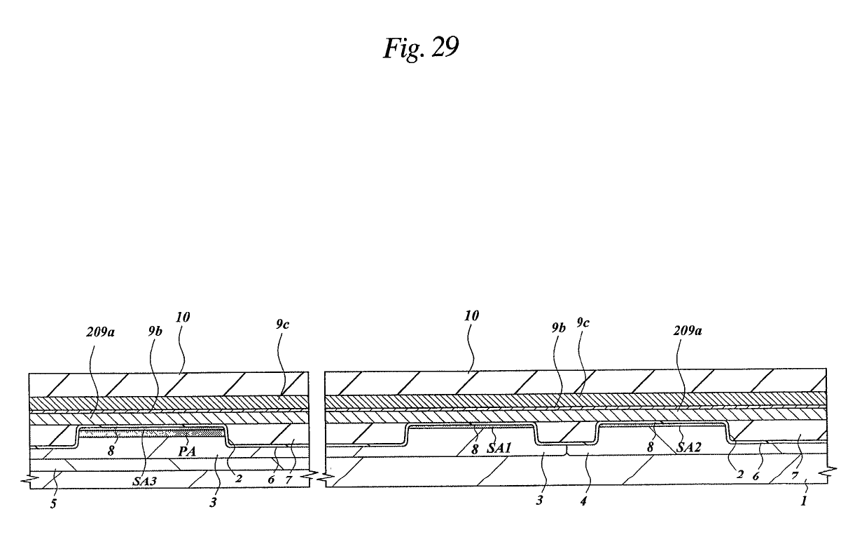

As shown in FIG. 29, the WN film 9b with a thickness of about 5 nm and the W film 9c with a thickness of about 80 nm are then deposited over the SiGe film 209a by a sputtering method, and further a silicon nitride film 10 with a thickness of about 220 nm is deposited over them by a CVD method.

Then, a heat treatment is performed in an inert gas atmosphere such as nitrogen at about 800° C. for the purpose of stress relaxation of the W film 9c and densifying the WN film 9b.

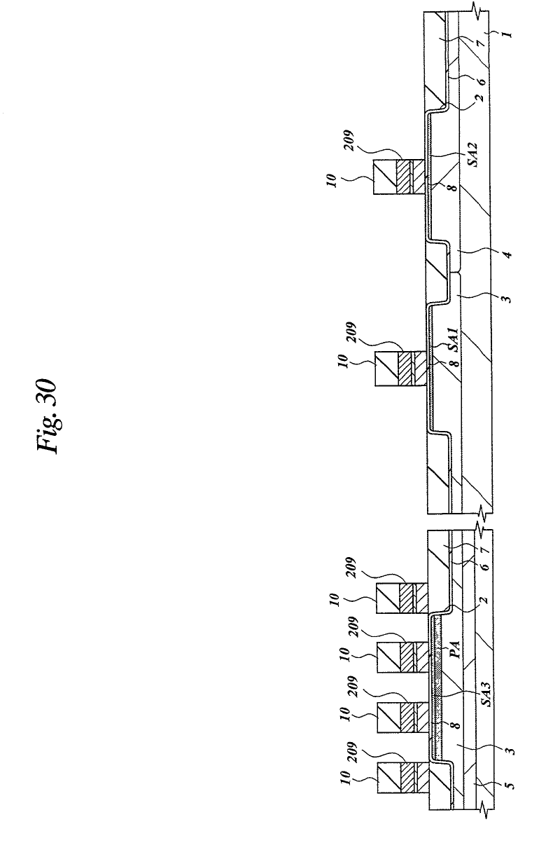

Thereafter, dry etching is performed for the silicon nitride film 10, the W film 9c, the WN film 9b, and the polycrystal silicon film 9a while using a resist film (not shown) as a mask to form a gate electrode 209 (FIG. 30). The SiGe film on the p-type well 3 of the memory cell array may be made p-type by injecting impurity after a SiGe film which does not contain impurity is formed. In this case, the SiGe film on the p-type well 3 of the peripheral circuit forming region may be made n-type, and the SiGe film on the n-type well 4 of the peripheral circuit forming region may be made p-type.

Since the following processes are similar to those of the case of Embodiment 1 explained referring to the drawings after FIG. 14, the explanation thereof is omitted.

Thus, in the present embodiment, since the gate electrode 209 is constituted employing the SiGe film 209a, the resistance value can be reduced.

Further, since the work function of the gate electrode is in the approximately middle of the n-type polycrystal silicon and the p-type polycrystal silicon, the threshold value thereof can be made high compared with that of the case where the gate electrode is the n-type. Therefore, the substrate concentration (the threshold value regulating impurity region SA3) can be reduced, and the junction leak of the n⁺ type semiconductor region 17 connected to the capacitor C can be reduced. Accordingly, the retention characteristic of the memory cell can be improved.

Even when the substrate concentration is reduced, since the punch-through prevention region PA is formed, the expanse of the depletion layer from the source and the drain can be restrained, and the increase in the leak current due to the punch-through phenomenon can be prevented.

Moreover, since the punch-through prevention region PA is formed by injecting In ions, In ions exist at a sharp concentration profile, and an increase in the substrate concentration (the threshold value regulating impurity region SA3) cannot be brought about.

(Embodiment 4)

Although the gate electrode 9p of the information transferring MISFET is formed by injecting B ions into the polycrystal silicon film 9a in Embodiment 1, in the present embodiment, adopted is so called a negative word line technique in which B ions are not injected but P ions are injected and the gate electrode of an MISFET is biased at a negative electric potential.

Since a semiconductor integrated circuit device of the present embodiment has the same structure as that of Embodiment 1, except that B ions are not injected into the gate electrode 9p of the information transferring MISFET Qs, detailed explanation regarding the structure and a fabrication method thereof are omitted.

Here, the gate electrode of the MISFET, that is, the electric potential of the word line WL (gate electrode) of the time of not selecting a memory cell, is set to be lower than that of a reference electric potential and to be negative. This non-selective electric potential is, for example, set to be about −0.5 to −1 V.

As a result, since the threshold value Vt of the information transferring MISFET Qs of the non-selective time substantially becomes high, the substrate concentration (the threshold value regulating impurity region SA3) can be reduced. Therefore, the junction leak of the n⁺ type semiconductor region 17 connected to the capacitor C can be reduced, and the retention characteristic of the memory cell can be improved.

Even when the substrate concentration is reduced, since the punch-through prevention region PA is formed, the expanse of the depletion layer from the source and the drain can be restrained, and the increase in the leak current due to the punch-through phenomenon can be prevented.

Moreover, since the punch-through prevention region PA is formed by injecting In ions, In ions exist at a sharp concentration profile, and an increase in the substrate concentration (the threshold value regulating impurity region SA3) cannot be brought about.

While the invention made by the present inventors has been described specifically with reference to the embodiments, the present invention is not limited thereto, and it is needless to say that various changes can be made thereto within the scope not departing from the substance of the invention.

Effects obtained by a typical one of the features disclosed in the present application will briefly be described as follows:

According to the present invention, since the punch-through prevention region is formed by an impurity such as for example In atoms whose weight is heavier than an impurity for regulating the threshold value, such as B atom, the punch-through phenomenon can be restrained without bringing about an increase in the substrate concentration (the threshold value regulating impurity region concentration). By restraining the punch-through phenomenon, unevenness in characteristics of the MISFET can be reduced.

Specifically, when the present invention is applied to a memory cell of a DRAM, the punch-through phenomenon can be restrained while improving the retention time. By restraining the punch-through phenomenon, unevenness in characteristics of the information transferring MISFET of a memory cell can be reduced.

What is claimed is:

1. A semiconductor integrated circuit device having an n-channel type MISFET, said n-channel type MISFET comprising:
(a) a source and a drain formed in a semiconductor substrate;
(b) a gate electrode formed on the semiconductor substrate between the source and the drain via a gate isolation film, said gate electrode having a p-type impurity;
(c) a first impurity region for regulating a threshold value formed in the semiconductor substrate under the gate electrode; and
(d) a second impurity region for preventing punch-through formed to cover end portions of the source and the drain at a position deeper than the first impurity region, said second impurity region having an impurity including an atom whose weight is heavier than that of an impurity atom in the first impurity region.

2. The semiconductor integrated circuit device as set forth in claim 1, wherein the impurity constituting the second impurity region is In (indium).

3. The semiconductor integrated circuit device as set forth in claim 1, wherein the impurity constituting the first impurity region is B (boron) or a boron fluoride compound.

4. The semiconductor integrated circuit device as set forth in claim 1, wherein the gate electrode is made of SiGe.

5. The semiconductor integrated circuit device as set forth in claim 1, wherein the n-channel type MISFET is an information transferring MISFET constituting a DRAM.

6. A semiconductor integrated circuit device having an information transferring MISFET constituting a memory cell of a DRAM, said information transferring MISFET comprising:
(a) a source and a drain formed in a semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode; and
(d) a second impurity region for preventing punch-through formed to cover end portions of the source and the drain at a position deeper than the first impurity region, said second impurity region having an impurity including an atom whose weight is heavier than that of an impurity atom in the first impurity region.

7. A semiconductor integrated circuit device having an n-channel type MISFET, said n-channel type MISFET comprising:
(a) a source and a drain formed in a semiconductor substrate;
(b) a gate electrode formed on the semiconductor substrate between the source and the drain via a gate isolation film, said gate electrode having a p-type impurity;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions.

8. The semiconductor integrated circuit device as set forth in claim 7, wherein the gate electrode is made of SiGe.

9. The semiconductor integrated circuit device as set forth in claim 7, wherein the n-channel type MISFET is an information transferring MISFET constituting a DRAM.

10. A semiconductor integrated circuit device having an information transferring MISFET constituting a memory cell of a DRAM, said information transferring MISFET comprising:
(a) a source and a drain formed in a semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions.

11. A semiconductor integrated circuit device having a first conductive type MISFET, said semiconductor integrated circuit device comprising:
(a) a source and a drain formed in a semiconductor substrate;
(b) a gate electrode formed on the semiconductor substrate between the source and the drain via a gate isolation film, said gate electrode having a second conductive type impurity that is the conductive type opposite to the first conductive type;
(c) a first impurity region for regulating a threshold value formed in the semiconductor substrate under the gate electrode, said first impurity region having the second conductive type impurity; and
(d) a second impurity region for preventing punch-through formed to cover end portions of the source and the drain at a position deeper than the first impurity region, said second impurity region having a second conductive type impurity including an atom whose weight is heavier than that of an impurity atom in the first impurity region.

12. A semiconductor integrated circuit device having a memory cell comprising an information transferring n-channel type MISFET and a capacity element formed in a memory cell forming region of a semiconductor substrate and an n-channel type MISFET and having a p-channel type MISFET formed in a peripheral circuit forming region, said information transferring n-channel type MISFET comprising:
(a) a source and a drain formed in the semiconductor substrate;
(b) a gate electrode formed on the semiconductor substrate between the source and the drain via a gate isolation film, said gate electrode having a second conductive type impurity that is the conductive type opposite to a first conductive type;
(c) a first impurity region for regulating a threshold value formed in the semiconductor substrate under the gate electrode, said first impurity region having the second conductive type impurity; and
(d) a second impurity region for preventing punch-through formed to cover end portions of the source and the drain at a position deeper than the first impurity region, said second impurity region having a second conductive type impurity including an atom whose weight is heavier than that of an impurity atom in the first impurity region.

13. The semiconductor integrated circuit device as set forth in claim 12, wherein the impurity constituting the second impurity region is In.

14. The semiconductor integrated circuit device as set forth in claim 12, wherein the impurity constituting the first impurity region is B (boron) or a boron fluoride compound.

15. The semiconductor integrated circuit device as set forth in claim 12, wherein the gate electrode is made of SiGe.

16. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region, said information transferring n-channel type MISFET comprising:
(a) a source and a drain formed in the semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode, said first impurity region having a second conductive type impurity; and
(d) a second impurity region for preventing punch-through formed to cover end portions of the source and the drain at a position deeper than the first impurity region, said second impurity region having a second conductive type impurity including an atom whose weight is heavier than that of an impurity atom in the first impurity region.

17. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region, said information transferring n-channel type MISFET comprising:
(a) a source and a drain formed in the semiconductor substrate;
(b) a gate electrode formed on the semiconductor substrate between the source and the drain via a gate isolation film, said gate electrode having a p-type impurity;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions.

18. The semiconductor integrated circuit device as set forth in claim 17, wherein the gate electrode is made of SiGe.

19. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region, said information transferring n-channel type MISFET comprising:
(a) a source and a drain formed in the semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions.

20. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region,
said information transferring n-channel type MISFET comprising:
(a) a source and a drain formed in the semiconductor substrate;
(b) a gate electrode formed on the semiconductor substrate between the source and the drain via a gate isolation film, said gate electrode having a p-type impurity;
(c) a first impurity region for regulating a threshold value formed in the semiconductor substrate under the gate electrode; and
(d) a second impurity region for preventing punch-through formed to cover end portions of the source and the drain at a position deeper than the first impurity region, said second impurity region having an impurity including an atom whose weight is heavier than that of an impurity atom in the first impurity region;
said n-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having an n-type impurity; and
said p-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having a p-type impurity.

21. The semiconductor integrated circuit device as set forth in claim 20, wherein the impurity constituting the second impurity region is In.

22. The semiconductor integrated circuit device as set forth in claim 20, wherein the impurity constituting the first impurity region is B (boron) or a boron fluoride compound.

23. The semiconductor integrated circuit device as set forth in claim 20, wherein the gate electrode is made of SiGe.

24. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region,
said information transferring n-channel type MISFET comprising:
(a) a source and a drain formed in the semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode; and
(d) a second impurity region for preventing punch-through formed to cover end portions of the source and the drain at a position deeper than the first impurity region, said second impurity region having an impurity including an atom whose weight is heavier than that of an impurity atom in the first impurity region;
said n-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having an n-type impurity; and
said p-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having a p-type impurity.

25. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region,
said information transferring n-channel type MISFET comprising:
(a) a source and a drain formed in the semiconductor substrate;
(b) a gate electrode formed on the semiconductor substrate between the source and the drain via a gate isolation film, said gate electrode having a p-type impurity;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions;
said n-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having an n-type impurity; and
said p-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having a p-type impurity.

26. The semiconductor integrated circuit device as set forth in claim 25, wherein the gate electrode is made of SiGe.

27. A semiconductor integrated circuit device having a memory cell comprising an information transferring n-channel type MISFET and a capacity element formed in a memory cell forming region of a semiconductor substrate and having an n-channel type MISFET and a p-channel type MISFET formed in a peripheral circuit forming region,
said information transferring n-channel type MISFET comprising:
(a) a source and a drain formed in the semiconductor substrate;
(b) a gate electrode formed on the semiconductor substrate between the source and the drain via a gate isolation film, said gate electrode being biased by a negative potential at a time of not selecting the memory cell;
(c) a first impurity region for regulating a threshold value formed in the semiconductor substrate under the gate electrode, said first impurity region being implanted with In ions; and
(d) a second impurity region for preventing punch-through formed to cover end portions of the source and the drain at a position deeper than the first impurity region, said second impurity region being implanted with In ions;
said n-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having an n-type impurity; and
said p-channel type MISFET formed in the peripheral circuit region comprising:
(a) a source and a drain formed in the semiconductor substrate; and
(b) a gate electrode formed on the semiconductor substrate between the source and the drain via a gate isolation film, said gate electrode having a p-type impurity.

28. A method of manufacturing a semiconductor integrated circuit device having an n-channel type MISFET, said method comprising the steps of:
(a) forming a first impurity region for regulating a threshold value by implanting an impurity into a semiconductor substrate main surface;
(b) forming a second impurity region for preventing punch-through in a region deeper than the first impurity region by implanting an impurity including an atom whose weight is heavier than that of an impurity atom in the first impurity region;
(c) forming a gate isolation film on the semiconductor substrate;
(d) forming a polycrystal silicon film or an SiGe film having a p-type impurity on the gate isolation film to form a p-type gate electrode by patterning; and
(e) forming source and drain regions by implanting an impurity into both sides of the gate electrode.

29. The method of manufacturing the semiconductor integrated circuit device as set forth in claim 28, wherein the impurity constituting the second impurity region is In.

30. The method of manufacturing the semiconductor integrated circuit device as set forth in claim 28, wherein the impurity constituting the first impurity region is B (boron) or a boron fluoride compound.

31. The method of manufacturing the semiconductor integrated circuit device as set forth in claim 28, further comprising a step of heat treatment process after the formation of the second impurity region.

32. A method of manufacturing a semiconductor integrated circuit device having an n-channel type MISFET, said method comprising the steps of:
(a) forming a first impurity region for regulating a threshold value by implanting an impurity into a semiconductor substrate main surface;
(b) forming a gate isolation film on the semiconductor substrate;
(c) forming a polycrystal silicon film or an SiGe film having a p-type impurity on the gate isolation film to form a p-type gate electrode by patterning;
(d) forming a second impurity region for preventing punch-through by implanting in both sides of the gate electrode an impurity including an atom whose weight is heavier than that of an impurity atom in the first impurity region; and
(e) forming source and drain regions by implanting an impurity into both sides of the gate electrode.

33. The method of manufacturing the semiconductor integrated circuit device as set forth in claim 32, wherein the impurity constituting the second impurity region is In.

34. The method of manufacturing the semiconductor integrated circuit device as set forth in claim 32, wherein the impurity constituting the first impurity region is B (boron) or a boron fluoride compound.

35. The method of manufacturing the semiconductor integrated circuit device as set forth in claim 32, further comprising a step of heat treatment process after the formation of the second impurity region.

36. A method of manufacturing a semiconductor integrated circuit device having a memory cell comprising an information transferring n-channel type MISFET and a capacity element formed in a memory cell forming region of a semiconductor substrate and having CMIS constituting n-channel type MISFET and p-channel type MISFET formed in a peripheral circuit forming region, said method comprising the steps of:
(a) forming a first impurity region for regulating a threshold value in an information transferring n-channel type MISFET forming region and a CMIS constituting n-channel type MISFET forming region by implanting an impurity into a semiconductor substrate main surface;
(b) forming a second impurity region for preventing punch-through in the information transferring n-channel type MISFET forming region and in a region deeper than the first impurity region by implanting an impurity including an atom whose weight is heavier than that of an impurity atom in the first impurity region;
(c) forming a gate isolation film in the information transferring n-channel type MISFET forming region and a CMIS constituting n-channel type MISFET and p-channel type MISFET forming region;
(d) forming a polycrystal silicon film or an SiGe film on the gate isolation film to perform patterning,
(e) forming a second impurity region for preventing punch-through in both sides of the gate electrode by implanting an impurity including an atom whose weight is heavier than that of an impurity atom in the first impurity region; and
(f) forming source and drain regions by implanting an impurity into both sides of the gate electrode.

37. The method of manufacturing the semiconductor integrated circuit device as set forth in claim 36, wherein the impurity constituting the second impurity region is In.

38. The method of manufacturing the semiconductor integrated circuit device as set forth in claim 36, wherein the impurity constituting the first impurity region is B (boron) or a boron fluoride compound.

39. The method of manufacturing the semiconductor integrated circuit device as set forth in claim 36, further comprising a step of heat treatment process after the formation of the second impurity region.

40. A method of manufacturing a semiconductor integrated circuit device having a memory cell comprising an information transferring n-channel type MISFET and a capacity element formed in a memory cell forming region of a semiconductor substrate and having CMIS constituting n-channel type MISFET and p-channel type MISFET formed in a peripheral circuit forming region, said method comprising the steps of:
(a) forming a first impurity region for regulating a threshold value in an information transferring n-channel type MISFET forming region and a CMIS constituting n-channel type MISFET forming region by implanting an impurity into a semiconductor substrate main surface;
(b) forming a gate isolation film in the information transferring n-channel type MISFET forming region and a CMIS constituting n-channel type MISFET and p-channel type MISFET forming region;
(c) forming a polycrystal silicon film or an SiGe film on the gate isolation film to perform patterning;
(d) forming a second impurity region for preventing punch-through in both sides of the gate electrode by implanting an impurity including an atom whose weight is heavier than that of an impurity atom in the first impurity region; and
(e) forming source and drain regions by implanting an impurity into both sides of the gate electrode.
